(19) United States
(12) Patent Application Publication
(10) Pub. No.: US 2014/0204357 A1
(43) Pub. Date: Jul. 24, 2014

(54) DETECTION APPARATUS, MEASUREMENT APPARATUS, LITHOGRAPHY APPARATUS, AND METHOD OF MANUFACTURING ARTICLE

(71) Applicant: CANON KABUSHIKI KAISHA, Tokyo (JP)

(72) Inventors: Toshihiko NISHIDA, Utsunomiya-shi (JP); Wataru Yamaguchi, Utsunomiya-shi (JP)

(73) Assignee: CANON KABUSHIKI KAISHA, Tokyo (JP)

(21) Appl. No.: 14/153,574

(22) Filed: Jan. 13, 2014

(30) Foreign Application Priority Data
Jan. 22, 2013 (JP) 2013-009615

(51) Int. Cl. G03F 9/00; G01B 11/14

(52) U.S. Cl. CPC G03F 9/7088; G01B 11/14
USPC 355/72; 356/614; 355/77

(57) ABSTRACT

The present invention provides a detection apparatus including a detector configured to detect a mark including a plurality of patterns arrayed on an object in a first direction, the apparatus comprising a support configured to support at least a part of the detector, wherein the support is configured to support the at least the part such that a displacement of the at least the part in a second direction corresponding to the first direction is smaller than a displacement of the at least the part in a third direction perpendicular to the second direction.

### BACKGROUND OF THE INVENTION

1. Field of the Invention

The present invention relates to a detection apparatus, a measurement apparatus, a lithography apparatus, and a method of manufacturing an article.

2. Description of the Related Art

A semiconductor device having a fine circuit pattern is manufactured through a lithography process for forming a resist pattern on a substrate. Recently, along with further micropatterning and higher integration of circuit patterns in semiconductor devices, lithography apparatuses are requested to improve the resolving power. To achieve this, an exposure apparatus using EUV light (Extreme Ultra Violet; wavelength of 5 to 15 nm), a drawing apparatus using an electron beam (charged particle beam), and the like have been developed.

Such an exposure apparatus and drawing apparatus are generally equipped with a measurement apparatus which detects an alignment mark formed on a substrate and measures the position of a substrate. High accuracy is requested of the measurement apparatus. In Japanese Patent Laid-Open No. 2009-16761, a measurement apparatus includes a movable optical element, and moves this optical element to suppress a measurement error arising from coma aberration, an optical axis shift, or the like. In Japanese Patent Laid-Open No. 2009-4521, a measurement apparatus is fixed to a projection optical system by using two members having different thermal expansion coefficients. The two members are configured so that, upon a change of the temperature of an environment where the measurement apparatus is arranged, thermal deformation in one member cancels thermal deformation in the other member.

It is essential for the measurement apparatus disclosed in Japanese Patent Laid-Open No. 2009-16761 to include a driving device for driving the optical element in order to reduce a measurement error. The measurement apparatus disclosed in Japanese Patent Laid-Open No. 2009-4521 needs to be configured so that thermal deformation in one member cancels thermal deformation in the other member, which is disadvantageous to the degree of freedom of design.

### SUMMARY OF THE INVENTION

The present invention provides, for example, a detection apparatus including a detector configured to detect a mark, which is advantageous in precision with which a position of the mark is measured.

According to one aspect of the present invention, there is provided a detection apparatus including a detector configured to detect a mark including a plurality of patterns arrayed on an object in a first direction, the apparatus comprising: a support configured to support at least a part of the detector, wherein the support is configured to support the at least the part such that a displacement of the at least the part in a second direction corresponding to the first direction is smaller than a displacement of the at least the part in a third direction perpendicular to the second direction.

Further features of the present invention will become apparent from the following description of exemplary embodiments with reference to the attached drawings.

### BRIEF DESCRIPTION OF THE DRAWINGS

FIG. 1A is a view showing an optical system and supporting portion in a measurement apparatus according to the first embodiment;

FIG. 1B is a view showing the optical system and supporting portion in the measurement apparatus according to the first embodiment;

FIG. 2A is a view showing the optical system, the supporting portion, and an airtight container in the measurement apparatus according to the first embodiment;

FIG. 2B is a view showing the optical system, supporting portion, and airtight container in the measurement apparatus according to the first embodiment;

FIG. 3 is a view showing the optical system, supporting portion, and airtight container when viewed from the Z direction;

FIG. 4A is a view showing a modification of the shape of the supporting portion;

FIG. 4B is a view showing another modification of the shape of the supporting portion;

FIG. 4C is a view showing still another modification of the shape of the supporting portion;

FIG. 5A is a graph showing the shift amount of a detection portion when the optical system is displaced in the X direction;

FIG. 5B is a graph showing the shift amount of the detection portion when the optical system is displaced in the Y direction;

FIG. 6A is a view showing a line-and-space pattern included in a mark;

FIG. 6B is a view showing a plurality of dot patterns included in a mark;

FIG. 6C is a view showing a plurality of quadrangular patterns included in a mark;

FIG. 7 is a view showing a state in which reflected light enters the measurement apparatus via a mirror;

FIG. 8 is a view showing a state in which reflected light enters the measurement apparatus via mirrors;

FIG. 9 is a view showing the arrangement of a measurement apparatus when measuring an X measurement mark and Y measurement mark;

FIG. 10 is a view showing the arrangement of measurement apparatuses when measuring an X measurement mark and Y measurement mark;

FIG. 11 is a view showing the measurement apparatus according to the first embodiment;

FIG. 12 is a view showing a drawing apparatus using the measurement apparatus;

FIG. 13 is a view showing the drawing apparatus using the measurement apparatus;

FIG. 14 is a view showing the drawing apparatus using the measurement apparatus; and

FIG. 15 is a view showing an exposure apparatus using the measurement apparatus.

### DESCRIPTION OF THE EMBODIMENTS

Exemplary embodiments of the present invention will be described below with reference to the accompanying drawings. Note that the same reference numerals denote the same members throughout the drawings, and a repetitive description thereof will not be given.

### First Embodiment

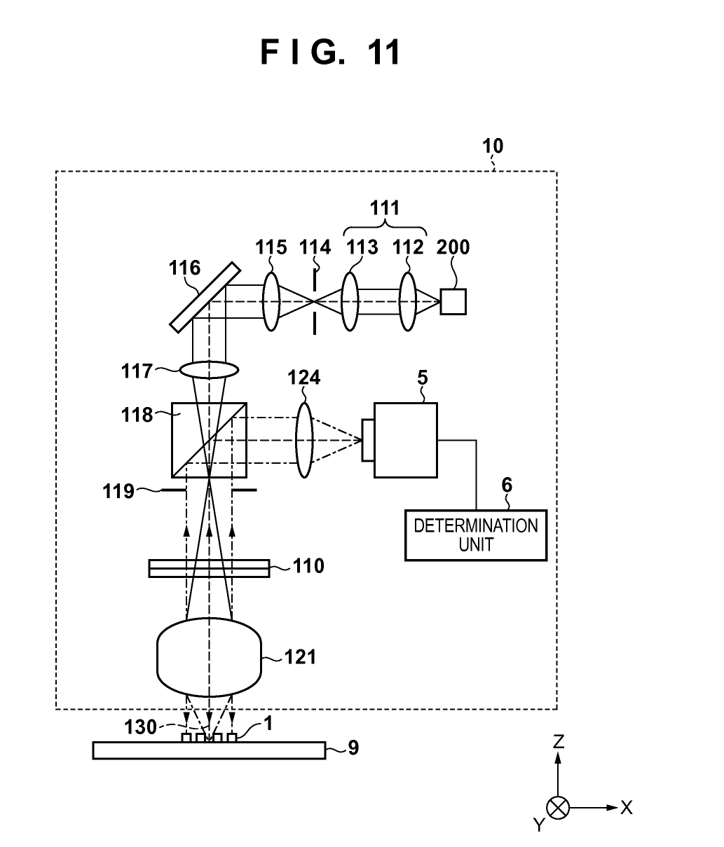

A measurement apparatus 10 according to the first embodiment of the present invention will be described with reference to FIG. 11. FIG. 11 is a view showing the measurement apparatus 10 according to the first embodiment. The measurement apparatus 10 can measure the position of a mark 1 by irradiating, with light, the mark 1 formed on a substrate 9 and detecting light 130 reflected by the mark 1. The measurement apparatus 10 includes a detector which detects the mark 1, and a determination unit 6 (processor) which determines the position of the mark 1 based on an output from the detector. The detector includes a light source 200, an illumination relay optical system 111 including optical elements 112 and 113, an aperture stop 114, an illumination optical system 115, a mirror 116, and a relay lens 117. The detector also includes a polarizing beam splitter 118, λ/4 plate 110, objective optical system 121, imaging optical system 124, and sensor 5.

Light emitted by the light source 200 passes through the illumination relay optical system 111, and reaches the aperture stop 114 arranged at a position corresponding to the pupil plane (optical Fourier transform plane with respect to the object plane) of the measurement apparatus 10. At this time, the diameter of the beam at the aperture stop 114 becomes much smaller than that of the beam emitted by the light source 200. By changing the aperture amount, the aperture stop 114 can adjust the numerical aperture of illumination light for illuminating the mark 1 formed on the substrate (on the object). The light having passed through the aperture stop 114 enters the polarizing beam splitter 118 via the illumination optical system 115, mirror 116, and relay lens 117. The light is then split into light having a p-polarized component parallel to the Y direction and light having an s-polarized component parallel to the X direction. The light having the p-polarized component passes through the polarizing beam splitter 118 and enters the λ/4 plate 110 via an aperture stop 119. The light which has entered the λ/4 plate 110 is converted into circularly polarized light, passes through the objective optical system 121, and Koehler-illuminates the mark 1 formed on the substrate 9.

The light 130 reflected by the mark 1 formed on the substrate 9 changes into circularly polarized light in a polarization state opposite to that of the circularly polarized light entering the mark 1. For example, when the polarization state of light entering the mark 1 is clockwise circular polarization, the polarization state of the light 130 reflected by the mark 1 is counterclockwise circular polarization. The reflected light 130, which has become circularly polarized light opposite to circularly polarized light entering the mark 1, passes through the objective optical system 121 and then through the λ/4 plate 110, is converted from the circularly polarized light into s-polarized light, and reaches the aperture stop 119. By changing the aperture amount, the aperture stop 119 can adjust the numerical aperture of the light 130 reflected by the mark 1. The reflected light having passed through the aperture stop 119 is reflected by the polarizing beam splitter 118, and then enters the sensor 5 via the imaging optical system 124. The sensor 5 can detect the light 130 reflected by the mark 1.

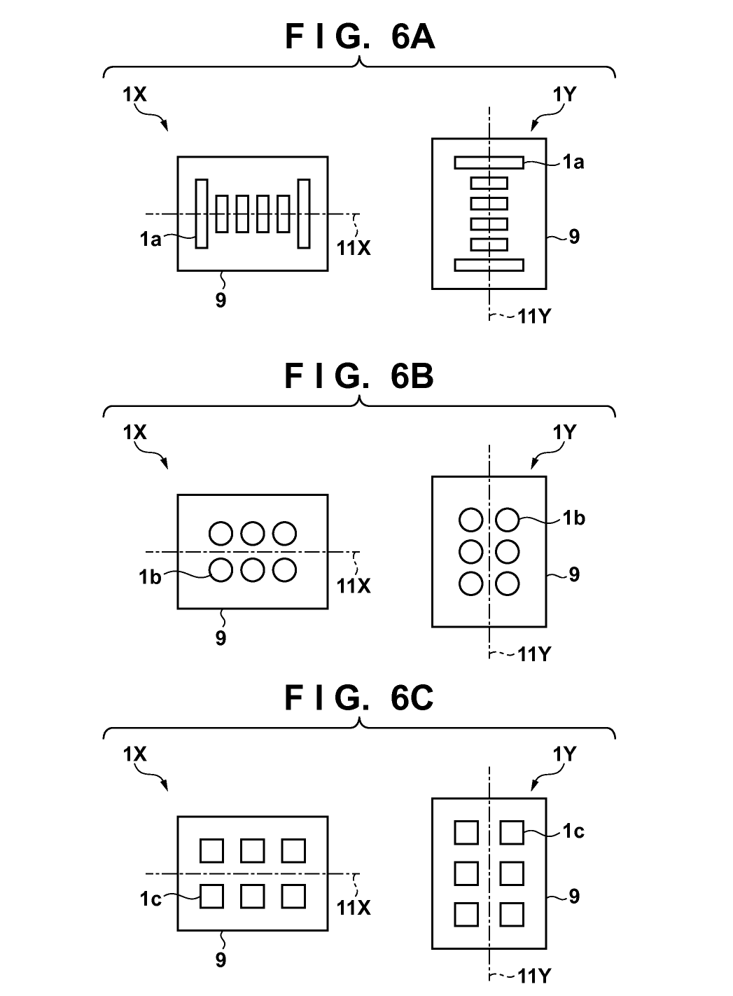

The mark 1 formed on the substrate includes a plurality of patterns arrayed in a predetermined direction (first direction (for example, X direction)). For example, as shown in the left view of FIG. 6A, the mark 1 includes a line-and-space pattern 1a in which a plurality of line patterns are arrayed in the X direction. The substrate 9 is held by a substrate stage (not shown) movable in the X, Y, and Z directions. The measurement apparatus 10 can form a light intensity distribution in the X direction in the mark 1 on the substrate by detecting the reflected light 130 by the sensor 5 while moving the mark 1 (substrate) in the X direction (first direction) by the substrate stage. In the measurement apparatus 10, the determination unit 6 (processor) can determine the position of the mark 1 in the first direction based on the light intensity distribution (output from the detector) detected by the sensor 5. For example, assume that the mark 1 is configured to include a line-and-space pattern in which a plurality of line patterns 1Xa are arrayed in the X direction, as shown in the left view of FIG. 6A. In this case, while moving the substrate 9 in the X direction, the sensor 5 receives the reflected light 130 to detect a light intensity distribution on a chain line 11X. The position of the mark 1 is obtained based on the intensity distribution of the detected reflected light.

Recently, along with further micropatterning and higher integration of circuit patterns in semiconductor devices, the measurement apparatus 10 needs to measure the position of the mark 1 at high accuracy. That is, when the measurement apparatus 10 measures the position of the mark 1, generation of a measurement error needs to be reduced. Generally in the measurement apparatus 10, the position of the optical system shifts (is displaced) owing to a manufacturing error or assembly adjustment error of the optical system, a change of the environment such as the air temperature, air pressure, or vibration, or the like, and an error (TIF: Tool Induced Shift) may arise from the optical system of the measurement apparatus. Examples of the TIS are coma aberration and spherical aberration. If the TIS is generated, a portion (to be referred to as a detection portion hereinafter) where reflected light is detected on the mark 1 shifts, and the measurement apparatus 10 cannot measure the position of the mark 1 at high accuracy. That is, the measurement error in the measurement apparatus 10 arises from the displacement of at least part (for example, the optical system) of the detector.

As described above, the measurement apparatus 10 according to the first embodiment performs measurement by using the mark 1 including a plurality of patterns arrayed in the first direction. When the detection portion shifts in the first direction (X direction) on the mark, this greatly influences a light intensity distribution to be detected by the sensor 5, generating a large measurement error. In contrast, when the detection portion shifts in a direction (Y direction) perpendicular to the first direction on the mark, the influence on the light intensity distribution is smaller than that when the detection portion shifts in the first direction (X direction). That is, when the detection portion on the mark shifts not in the first direction (X direction) but in the direction (Y direction) perpendicular to the first direction, the influence on the light intensity distribution can be lessened to decrease the measurement error generated when measuring the position of the mark 1. For this reason, the measurement apparatus 10 according to the first embodiment includes a supporting portion 4 (a support) which supports the optical system so that a displacement of the optical system in a predetermined direction (second direction) becomes smaller than a displacement of the optical system in a direction (third direction) perpendicular to the predetermined direction (second direction). The second direction is a direction corresponding to the first direction on the mark 1, and is the direction of a displacement of the optical system in which the detection portion on the mark shifts in the first direction. In the first embodiment, the second direction is a direction parallel to the first direction. Note that when the optical path of reflected light is deflected, the second direction can differ from the first direction.

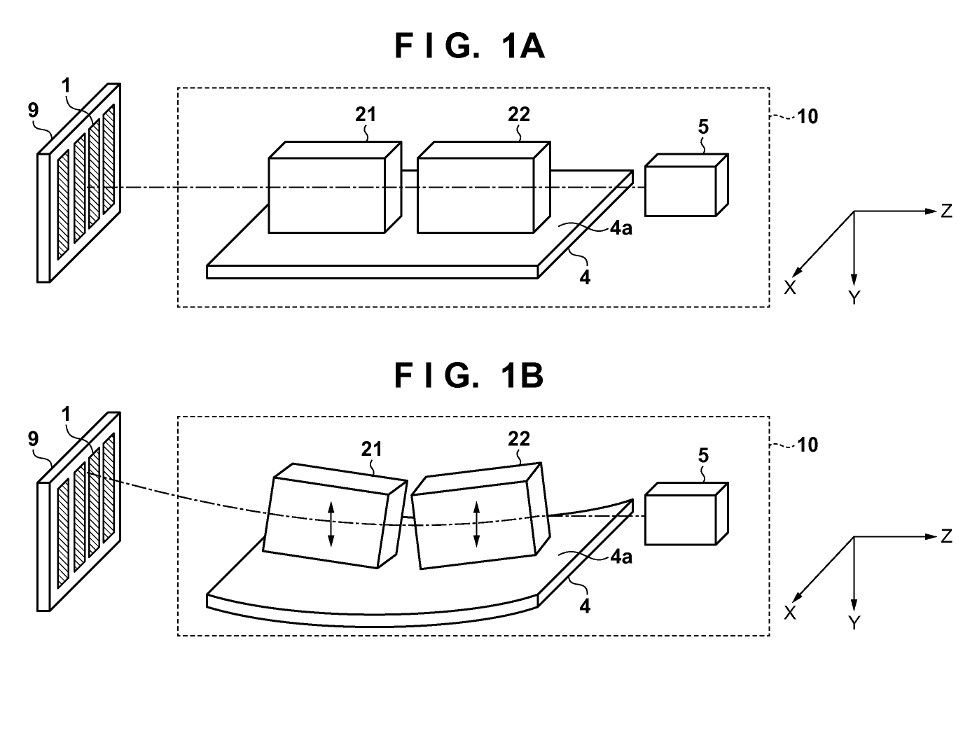

Support of the optical system by the supporting portion 4 in the measurement apparatus 10 according to the first embodiment will be explained with reference to FIGS. 1A and 1B. FIGS. 1A and 1B are views each showing the optical system and the supporting portion 4 which supports it in the measurement apparatus 10. For descriptive convenience, FIGS. 1A and 1B show only a path until light reflected by the mark 1 enters the sensor 5. The measurement apparatus 10 in FIGS. 1A and 1B is configured to include two optical systems 21 and 22 and the sensor 5. The optical systems 21 and 22 are assumed to be, for example, the objective optical system 121 and imaging optical system 124, respectively, but are not limited to them and suffice to be part of the detector, that is, optical members arranged on the path of reflected light. FIG. 1A is a view showing the measurement apparatus 10 in a state in which no displacement (decentering) is generated in the optical systems 21 and 22. FIG. 1B is a view showing the measurement apparatus 10 in a state in which a displacement is generated in the optical systems 21 and 22. The measurement apparatus 10 in the state in which no displacement is generated in the optical systems 21 and 22 will be explained with reference to FIG. 1A. As shown in FIG. 1A, the supporting portion 4 includes a supporting surface 4a parallel to the optical axes of the optical systems 21 and 22 and the second direction. The supporting surface 4a supports the optical systems 21 and 22. In FIGS. 1A and 1B, the second direction is the direction of a displacement of the optical system that generates a shift of the detection portion on the mark in the first direction (X direction), that is, the X direction. The supporting portion 4 configured and arranged in this manner supports the optical systems 21 and 22, and a displacement of the optical systems 21 and 22 in the X direction can be decreased. For example, when the temperature of an environment where the measurement apparatus 10 is arranged changes or vibrations propagate to the measurement apparatus 10, the supporting portion 4 greatly deforms in the Y direction but hardly deforms in the X direction, as shown in FIG. 1B. Thus, the optical systems 21 and 22 supported by the supporting portion 4 are displaced only in the third direction (Y direction) perpendicular to the second direction (X direction), and a displacement in the second direction (X direction) can be reduced. That is, a displacement of the optical systems 21 and 22 in the X direction can be decreased to be smaller than a displacement in the Y direction. Although the detection portion on the mark shifts in the Y direction, a shift in the X direction (first direction) that greatly influences the light intensity distribution can be decreased, and a measurement error generated when measuring the position of the mark 1 can be reduced.

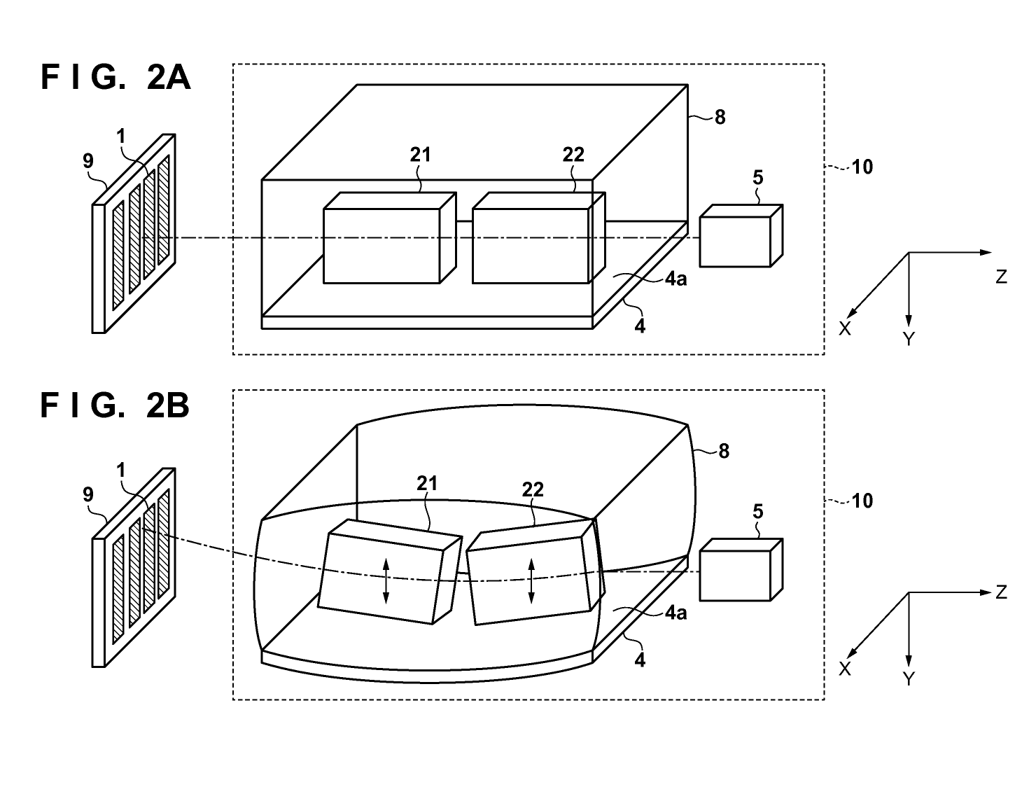

The measurement apparatus 10 according to the first embodiment can also include a container 8 which airtightly contains the optical systems 21 and 22 in cooperation with the supporting portion 4. For example, when the measurement apparatus 10 is arranged in vacuum, it is effective to airtightly contain the optical systems 21 and 22 by the supporting portion 4 and container 8. When the measurement apparatus 10 is arranged in vacuum, there may be a problem that a component generates gas, the vacuum environment cannot be maintained, and the component usable in the air environment cannot be used in the vacuum environment. Since the thermal conductivity drops in the vacuum environment, heat is accumulated in the measurement apparatus 10, causing thermal deformation or thermal destruction of a component or the like. However, the measurement apparatus 10 according to the first embodiment can solve the above-described problems by adopting the container 8 which airtightly contains the optical systems 21 and 22 in cooperation with the supporting portion 4. The measurement apparatus 10 including the container 8 will be explained with reference to FIGS. 2A and 2B. FIGS. 2A and 2B are views each showing the optical systems 21 and 22, the supporting portion 4 which supports them, and the container 8 which airtightly contains the optical systems 21 and 22 in cooperation with the supporting portion 4 in the measurement apparatus 10. For descriptive convenience, similar to FIGS. 1A and 1B, FIGS. 2A and 2B show only a path until light reflected by the mark 1 enters the sensor 5. FIG. 2A is a view showing the measurement apparatus 10 in a state in which no displacement (decentering) is generated in the optical systems 21 and 22. FIG. 2B is a view showing the measurement apparatus 10 in a state in which a displacement is generated in the optical systems 21 and 22. Since the supporting portion 4 and container 8 airtightly contain the optical systems 21 and 22, the optical systems 21 and 22 can be used even in the vacuum environment similarly to the air environment. However, when the inside of the container 8 is used as the air environment, a pressure difference is generated between the inside and outside of the container 8, and the container 8 is deformed, as shown in FIG. 2B. Even in this case, the optical systems 21 and 22 are supported by the supporting surface 4a of the supporting portion 4 and displaced in only the third direction (Y direction) perpendicular to the second direction, as in FIG. 1B, so a displacement in the second direction (X direction) can be reduced. Although the detection portion on the mark shifts in the Y direction, a shift in the X direction (first direction) that greatly influences the light intensity distribution can be decreased, and a measurement error generated when measuring the position of the mark 1 can be reduced.

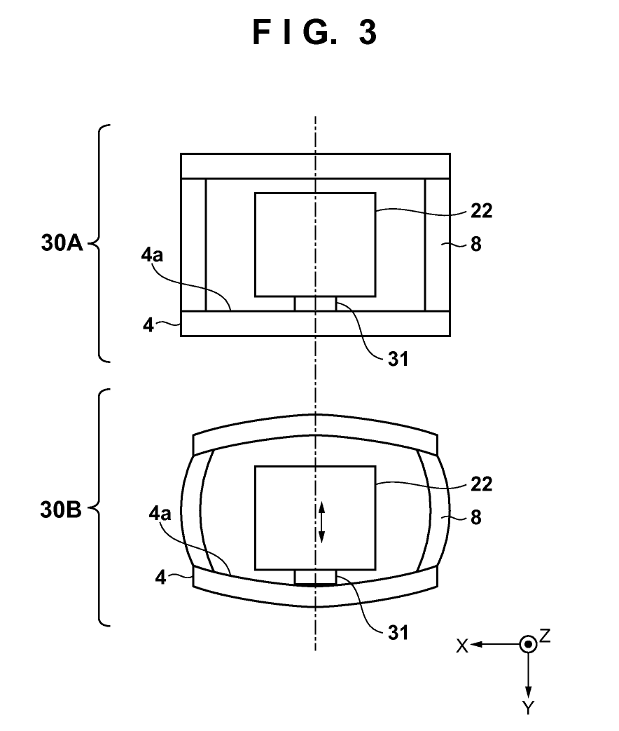

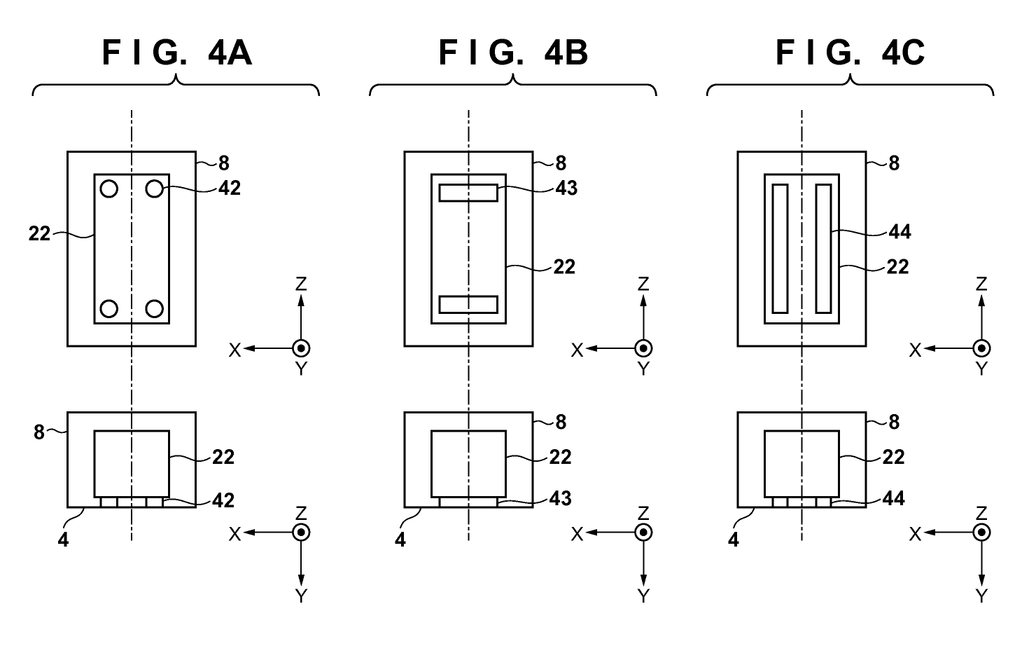

Next, a method of supporting the optical systems 21 and 22 by the supporting portion 4 will be explained with reference to FIGS. 3 and 4A to 4C. FIG. 3 is a view showing the optical system 22 (or optical system 21), supporting portion 4, and container 8 when viewed from the Z direction. In FIG. 3, 30A represents the measurement apparatus 10 in a state in which no displacement is generated in the optical system 22. In FIG. 3, 30B represents the measurement apparatus 10 in a state in which a displacement is generated in the optical system 22. As shown in FIG. 3, the optical system 22 is supported by the supporting portion 4 via supporting members 31 (spacers). The supporting members 31 are arranged at a plurality of positions symmetrical about a plane (Y-Z plane) which includes the optical axis of the optical system 22 and is perpendicular to the supporting surface 4a. By supporting the optical system 22 by the supporting portion 4 via the supporting members 31 in this way, the influence of the deformation of the supporting portion 4 on the optical system 22 can be reduced. A displacement of the optical system 22 in the Y direction can be decreased, compared to a case in which the supporting members 31 are not used. Note that the optical system 22 may be directly supported by the supporting surface 4a of the supporting portion 4 without the mediacy of the supporting member 31, as shown in FIGS. 1A and 2A.

FIGS. 4A to 4C are views showing modifications of the shape of the supporting member 31. In FIGS. 4A to 4C, the lower views show the optical system 22 when viewed from the Z direction, and the upper views show the optical system 22 when viewed from the Y direction. In FIG. 4A, the optical system 22 is supported by the supporting portion 4 using four columnar spacers 42 as the supporting members 31. The respective columnar spacers 42 are arranged near the corners of the optical system 22. In FIG. 4B, the optical system 22 is supported by the supporting portion 4 using, as the supporting members 31, two quadrangular prism spacers 43 elongated in the X direction. The respective quadrangular prism spacers 43 are arranged to be spaced apart in the Z direction. In FIG. 4C, the optical system 22 is supported by the supporting portion 4 using, as the supporting members 31, two quadrangular prism spacers 44 elongated in the Z direction. The respective quadrangular prism spacers 44 are arranged to be spaced apart in the X direction. In all FIGS. 4A to 4C, the supporting members 31 are arranged at a plurality of positions symmetrical about a plane (Y-Z plane) which includes the optical axis of the optical system 22 and is perpendicular to the supporting surface 4a. By supporting the optical system 22 by the supporting portion 4 via the supporting members 31 in this way, the influence of the deformation of the supporting portion 4 on the optical system 22 can be reduced. A displacement of the optical system 22 in the Y direction can be decreased, compared to a case in which the supporting members 31 are not used.

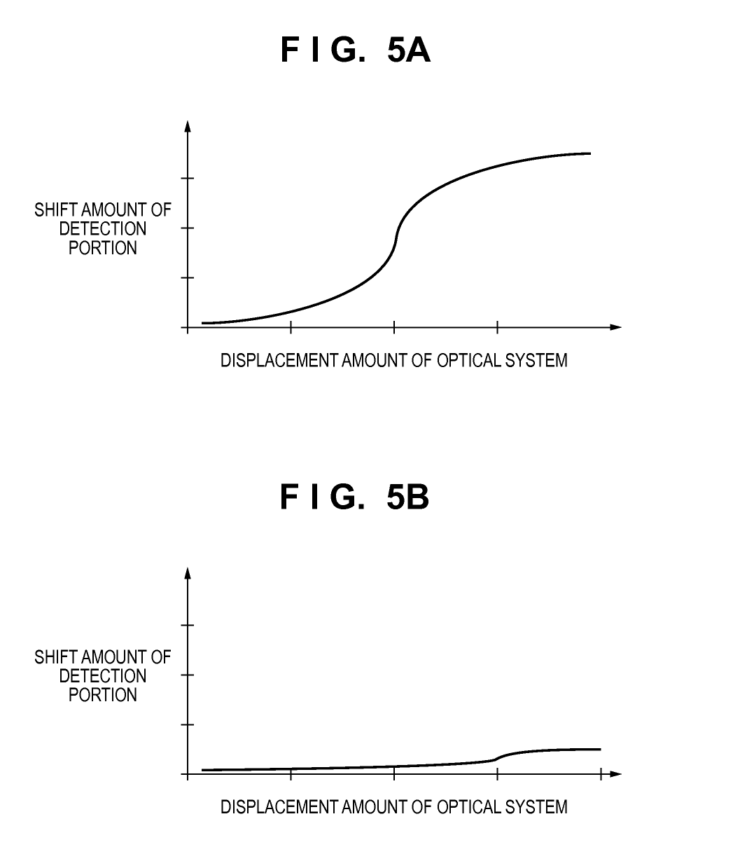

Here, the relationship between the amount (displacement amount) by which the optical system 22 is displaced, and the shift amount (coma aberration) of the detection portion will be described with reference to FIGS. 5A and 5B. For example, FIG. 5A is a graph showing the shift amount of the detection portion when the optical system 22 is displaced in the X direction in the measurement apparatus 10 shown in FIG. 1A. FIG. 5B is a graph showing the shift amount of the detection portion when the optical system 22 is displaced in the Y direction. When the optical system 22 is displaced in the Y direction (FIG. 5B), the shift amount (coma aberration) of the detection portion can be greatly reduced, compared to the case in which the optical system 22 is displaced in the X direction (FIG. 5A). That is, in the first embodiment, a measurement error can be greatly reduced by making the direction (third direction), in which the optical system 22 is displaced, coincide with a direction (Y direction) perpendicular to the first direction in which patterns are arrayed on a mark. Note that when the angle of the direction in which the optical system 22 is displaced and that of the direction perpendicular to the first direction have a difference (angle difference), the influence degree on the light intensity distribution that arises from the angle difference is given by the following equation (1):

influence degree on light intensity distribution that arises from angle error=amount (displacement amount) by which optical system is displaced×tan(angle difference) (1)

In this fashion, even when an angle difference is generated, the influence degree on the light intensity distribution can be calculated based on equation (1) to correct the light intensity distribution.

Next, patterns included in the mark 1 formed on the substrate will be described with reference to FIGS. 6A to 6C. FIGS. 6A to 6C are views each showing patterns included in the mark 1 formed on the substrate. FIG. 6A shows the line-and-space pattern 1a. FIG. 6B shows a plurality of dot patterns 1b. FIG. 6C shows a plurality of quadrangular patterns 1c. In each of FIGS. 6A to 6C, the left view shows a mark (an X measurement mark 1X) configured to detect a light intensity distribution in the X direction by the sensor 5. The X measurement mark 1X includes patterns arrayed in the X direction. In measuring the X measurement mark 1X, the measurement apparatus 10 (for example, FIG. 1A) configured to reduce a displacement of the optical systems 21 and 22 in the X direction when the first and second directions are defined as the X direction is used. The patterns shown in the left view of each of FIGS. 6A to 6C are preferably formed to be axisymmetric about a symmetry axis parallel to the X direction. Also, in each of FIGS. 6A to 6C, the right view shows a mark (a Y measurement mark 1Y) configured to detect a light intensity distribution in the Y direction by the sensor 5. The Y measurement mark 1Y includes patterns arrayed in the Y direction. In measuring the Y measurement mark 1Y, the measurement apparatus 10 configured to reduce a displacement of the optical systems 21 and 22 in the Y direction when the first and second directions are defined as the Y direction is used. The patterns shown in the right view of each of FIGS. 6A to 6C are preferably formed to be axisymmetric about a symmetry axis parallel to the Y direction. To measure the X measurement mark 1X and Y measurement mark 1Y, a measurement apparatus which measures the X measurement mark 1X, and a measurement apparatus which measures the Y measurement mark 1Y are used together, which will be described later (see FIG. 9). The line-and-space pattern 1a shown in FIG. 6A may have an equal- or unequal-interval pitch. Each of the patterns 1b and 1c shown in FIGS. 6B and 6C may have an unequal-interval pitch. A mark for detecting a light intensity distribution in the X direction and a mark for detecting a light intensity distribution in the Y direction may not be divided, and one mark may be configured to be able to detect a light intensity distribution in the X direction and a light intensity distribution in the Y direction. One mark is, for example, a mark in which the dot patterns 1b or quadrangular patterns 1c are arranged two-dimensionally.

As described above, the measurement apparatus 10 according to the first embodiment includes the supporting portion 4 which supports part (optical system) of the detector so that a displacement of the optical system in a predetermined direction (second direction) becomes smaller than a displacement of the optical system in a direction (third direction) perpendicular to the predetermined direction (second direction). The second direction is a direction corresponding to the direction (first direction) in which patterns are arrayed on the mark 1, and is also the direction of a displacement of the optical system that generates a shift of the detection portion on the mark in the first direction. Hence, a shift of the detection portion on the mark in a direction (first direction) that greatly influences the light intensity distribution can be decreased to reduce a measurement error generated when measuring the position of the mark 1. When a cylindrical lens is used as an optical member in the optical system, the influence on the light intensity distribution can be lessened by making the generatrix direction of the cylindrical lens coincide with the direction (third direction) in which the cylindrical lens is displaced.

### Second Embodiment

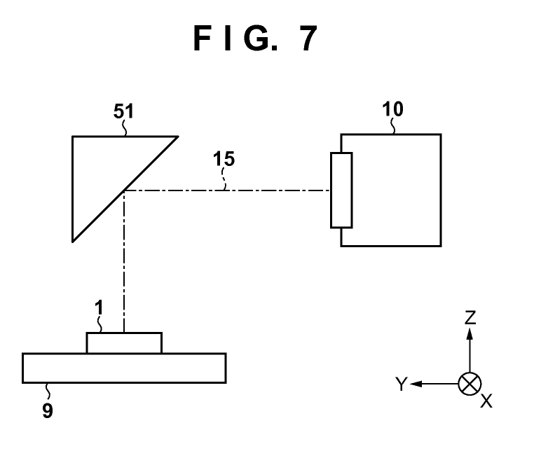

The second embodiment of the present invention will be described with reference to FIG. 7. The second embodiment is different from the first embodiment in that an optical path 15 of light reflected by a mark 1 is deflected by a mirror 51 and then the reflected light enters a measurement apparatus 10. FIG. 7 is a view showing a state in which the optical path of reflected light is deflected by the mirror 51 and then the reflected light enters the measurement apparatus 10 in the second embodiment.

In FIG. 7, the optical path 15 of light reflected by the mark 1 is deflected via the deflecting mirror 51, and then the reflected light enters the measurement apparatus 10. The measurement apparatus 10 includes a supporting portion 4 which supports the optical system so that a displacement of the optical system in a predetermined direction (second direction) becomes smaller than a displacement of the optical system in a direction (third direction) perpendicular to the predetermined direction (second direction). The second direction in the measurement apparatus 10 is set to correspond to the first direction on the mark even via the deflecting mirror 51. For example, in FIG. 7, since the first direction on the mark is the X direction, the second and third directions in the measurement apparatus 10 are the Y and Z directions, respectively. In this case, in the measurement apparatus 10, the supporting portion 4 supports the optical system so that a displacement of the optical system in the second direction (X direction) becomes smaller than a displacement in the third direction (Z direction) perpendicular to the second direction. In FIG. 7, the optical path 15 of light reflected by the mark 1 is deflected in the Y direction from the Z direction by the deflecting mirror 51, but is not limited to this and may be deflected in another direction (for example, X direction). Even in this case, in the measurement apparatus 10, the supporting portion 4 supports the optical system so that a displacement of the optical system in the predetermined direction (second direction) becomes smaller than a displacement of the optical system in a direction (third direction) perpendicular to the predetermined direction (second direction). For example, when the optical path 15 of light reflected by the mark 1 is deflected in the X direction from the Z direction by the deflecting mirror 51, the second direction serves as the Z direction and the third direction serves as the Y direction. Further, the measurement apparatus 10 is configured to support the optical system by the supporting portion 4 so that a displacement of the optical system in the Z direction becomes smaller than a displacement of the optical system in the Y direction.

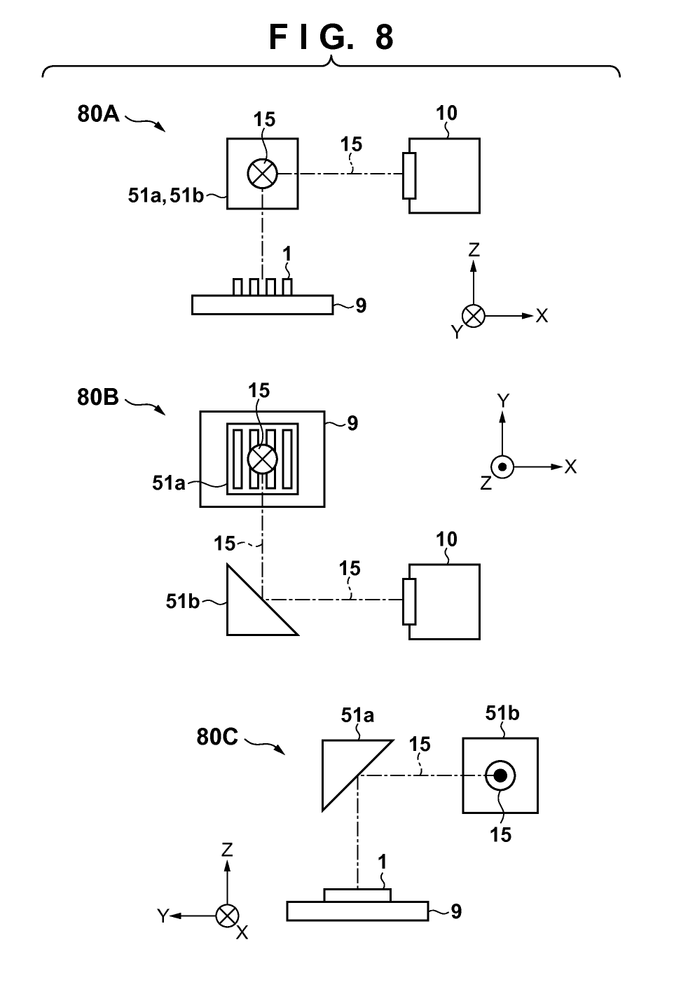

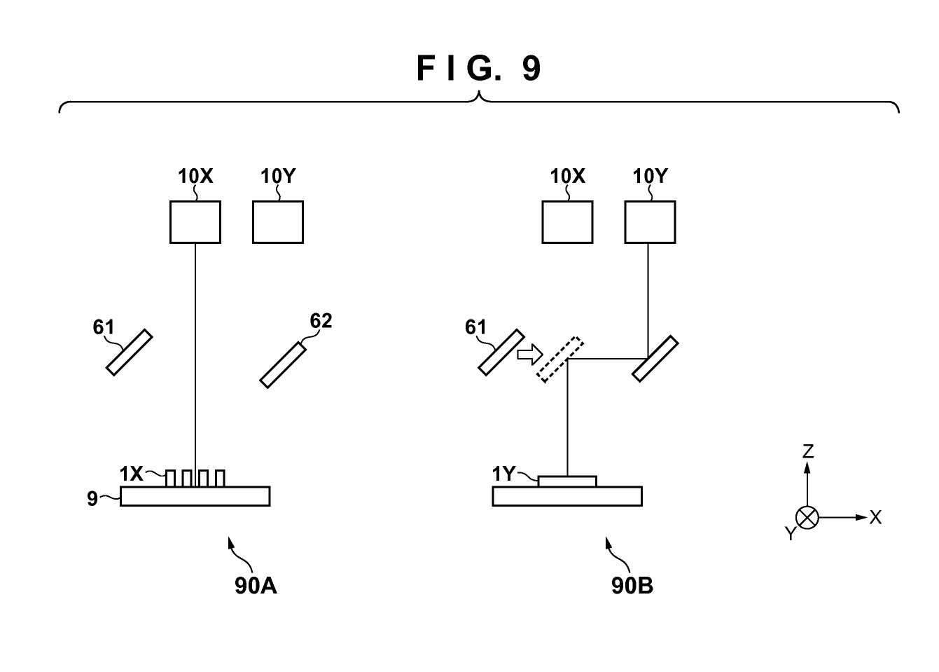

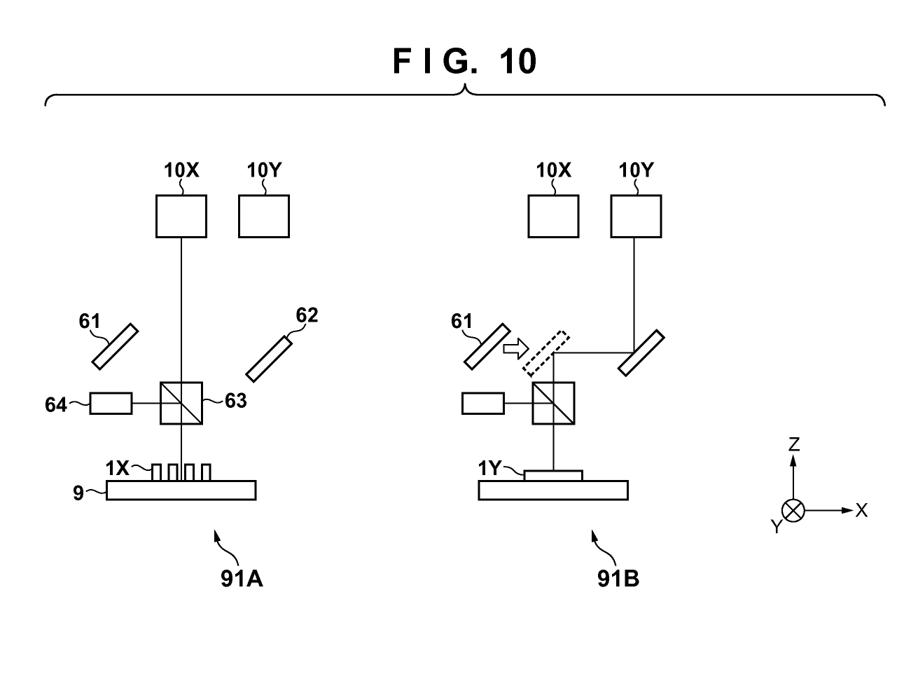

A case in which a plurality of (two) deflecting mirrors are used will be explained with reference to FIG. 8. FIG. 8 is a view showing a case in which light reflected by the mark 1 enters the measurement apparatus 10 via two deflecting mirrors 51a and 51b. In FIG. 8, 80A is a view taken in the Y direction. In FIG. 8, 80B is a view taken in the Z direction. In FIG. 8, 80C is a view taken in the X direction. Light reflected by the mark 1 enters the measurement apparatus 10 via the deflecting mirrors 51a and 51b. The measurement apparatus 10 includes the supporting portion 4 which supports the optical system so that a displacement of the optical system in a predetermined direction (second direction) becomes smaller than a displacement of the optical system in a direction (third direction) perpendicular to the predetermined direction (second direction). The second direction in the measurement apparatus 10 is set to correspond to the first direction on the mark even via the two deflecting mirrors 51a and 51b. For example, in FIG. 8, since the first direction on the mark is the X direction, the second and third directions in the measurement apparatus 10 are the Y and Z directions, respectively. In this case, in the measurement apparatus 10, the supporting portion 4 supports the optical system so that a displacement of the optical system in the Y direction becomes smaller than a displacement in the Z direction. In FIG. 8, the optical path 15 of light reflected by the mark 1 is deflected in the Y direction from the Z direction by the two deflecting mirrors 51a and 51b, but is not limited to this and may be deflected in another direction (for example, X direction). Even in this case, the second direction in the measurement apparatus 10 is set to correspond to the first direction on the mark even via the two deflecting mirrors. Although the two deflecting mirrors are used in FIG. 8, the present invention is not limited to this, and three or more deflecting mirrors may be used.

As described above, in the second embodiment, the optical path of light reflected by the mark 1 is deflected via the deflecting mirror 51 and enters the measurement apparatus 10. Even in this case, in the measurement apparatus 10, the supporting portion 4 supports the optical system so that a displacement of the optical system in the second direction becomes smaller than a displacement of the optical system in the third direction perpendicular to the second direction. At this time, the second direction is a direction corresponding to the direction (first direction) in which patterns are arrayed on the mark, and is also the direction of a displacement of the optical system that generates a shift of the detection portion on the mark in the first direction. Similar to the first embodiment, a shift of the detection portion on the mark in a direction (first direction) that greatly influences the light intensity distribution can be decreased to reduce a measurement error generated when measuring the position of the mark 1.

### Third Embodiment

The third embodiment of the present invention will be described with reference to FIG. 9. In the third embodiment, the arrangement of a measurement apparatus 10 when measuring an X measurement mark and Y measurement mark shown in FIGS. 6A to 6C will be explained. In FIG. 9, 90A shows a state in which the X measurement mark is measured. In FIG. 9, 90B shows a state in which the Y measurement mark is measured. FIG. 9 shows a measurement apparatus 10X for measuring an X measurement mark 1X, a measurement apparatus 10Y for measuring a Y measurement mark, and two mirrors 61 and 62 which deflect the optical path of light reflected by a mark 1. The mirror 61 is configured to be movable in the X direction by a driving mechanism (not shown).

When measuring the X measurement mark 1X, the mirror 61 is not arranged on the optical path of light reflected by the X measurement mark 1X, and the reflected light is caused to enter the measurement apparatus 10X, as represented by 90A of FIG. 9. In the measurement apparatus 10X, a supporting portion 4 supports the optical system so that a displacement of the optical system in the X direction serving as the second direction in the measurement apparatus 10X becomes smaller than a displacement of the optical system in the Y direction serving as the third direction. Accordingly, a shift of the detection portion on the X measurement mark 1X in a direction (first direction (X direction) on the X measurement mark 1X) that greatly influences the light intensity distribution can be decreased to reduce a measurement error generated when measuring the position of the X measurement mark 1X. To the contrary, when measuring a Y measurement mark 1Y, the mirror 61 is arranged on the optical path of light reflected by the Y measurement mark 1Y, and the reflected light is caused to enter the measurement apparatus 10Y via the mirrors 61 and 62, as represented by 90B of FIG. 9. In the measurement apparatus 10Y, the supporting portion 4 supports the optical system so that a displacement of the optical system in the Y direction serving as the second direction in the measurement apparatus 10Y becomes smaller than a displacement of the optical system in the X direction serving as the third direction. Therefore, a shift of the detection portion on the Y measurement mark 1Y in a direction (first direction (Y direction) on the Y measurement mark 1Y) that greatly influences the light intensity distribution can be decreased to reduce a measurement error generated when measuring the position of the Y measurement mark 1Y. In the third embodiment, as shown in FIG. 9, each of the measurement apparatuses 10X and 10Y includes an illumination optical system (a light source 200, illumination relay optical system 111, aperture stop 114, illumination optical system 115, mirror 116, and relay lens 117). However, the present invention is not limited to this, and in the third embodiment, the measurement apparatuses 10X and 10Y may share a common illumination optical system 64, as shown in FIG. 10. In this case, for example, as represented by 91A and 91B of FIG. 10, a prism 63 is arranged on an optical path common to light reflected by the X measurement mark 1X and light reflected by the Y measurement mark 1Y. In this arrangement, light emitted by the illumination optical system 64 is reflected by the prism 63 to irradiate the mark 1. The light reflected by the mark 1 passes through the prism and enters the measurement apparatus 10X or 10Y.

### Embodiments of Lithography Apparatus

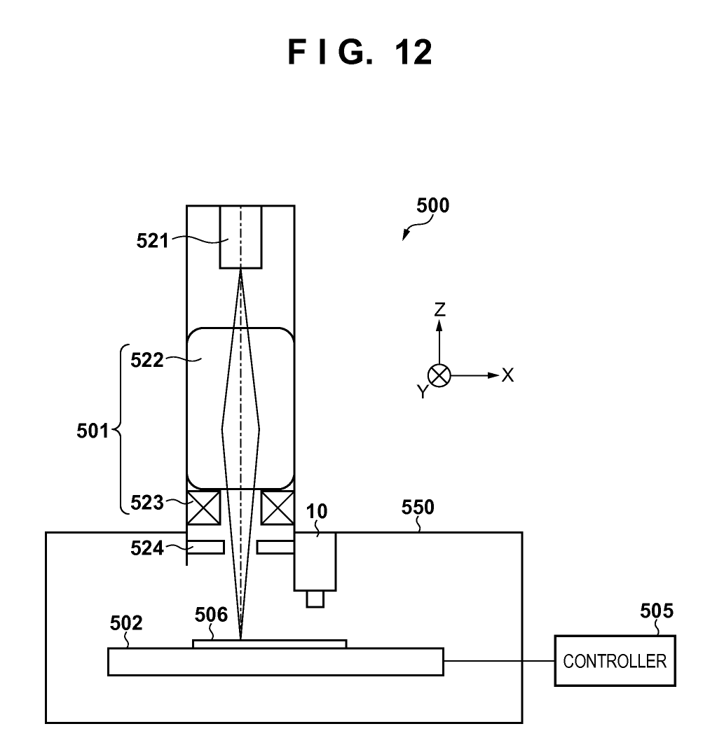

A drawing apparatus 500 and exposure apparatus 400 will be described as embodiments of a lithography apparatus including the above-described measurement apparatus. First, the drawing apparatus 500 using an electron beam (charged particle beam) will be explained with reference to FIG. 12. The drawing apparatus 500 includes an electron gun 521, an electron optical system 501, an electron measurement system 524, a substrate stage 502 which is movable while holding a substrate 506, a controller 505 which controls the position of the substrate stage 502, a measurement apparatus 10, and a vacuum chamber 550. The inside of the vacuum chamber 550 is evacuated by a vacuum pump (not shown). The electron optical system 501 is constructed from an electron lens system 522 which converges an electron beam emitted by the electron gun 521, and a deflector 523 which deflects the electron beam.

The drawing apparatus 500 includes the measurement apparatus 10 which measures the position of a mark formed on a substrate to align the substrate 506 and an electron beam or align a plurality of shot regions formed on the substrate 506. As the measurement apparatus 10, for example, the measurement apparatus 10 described in the first embodiment is applicable. In the drawing apparatus 500, the controller 505 controls the position of the substrate stage 502 based on the mark position measured by the measurement apparatus 10. The position of a mark formed on the substrate, that is, the position of the substrate 506 can therefore be measured at high accuracy.

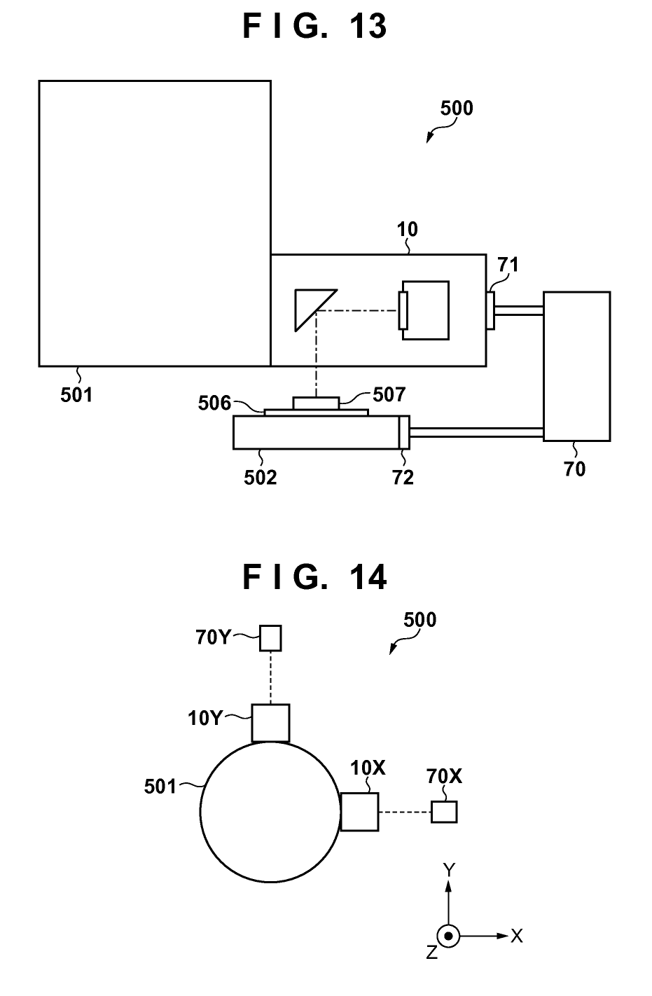

A method of controlling the position of the substrate stage 502 by the controller 505 of the drawing apparatus 500 will be described below with reference to FIGS. 13 and 14. The drawing apparatus 500 includes an interferometer 70 which measures the position of the substrate stage 502. The interferometer 70 can measure the position of the substrate stage 502 at high accuracy. For example, the interferometer 70 branches a laser beam emitted by a light source included in the interferometer 70, irradiates a reflecting plate 71 of the measurement apparatus 10 with one branched laser beam, and irradiates a reflecting plate 72 of the substrate stage 502 with the other laser beam. The laser beam reflected by the reflecting plate 71 and the laser beam reflected by the reflecting plate 72 are combined into interference light, and the wavelength (frequency) and phase difference of the interference light are measured. As a result, a displacement of the position of the substrate stage 502 with respect to the position (reference position) of the measurement apparatus 10 is detected, and the current position of the substrate stage 502 can be calculated. In the embodiment, the position of the substrate stage 502 with respect to that of the measurement apparatus 10 is measured using the interferometer 70. However, the present invention is not limited to this, and the measurement target is arbitrary as long as the relative position of the substrate stage 502 with respect to the position of the measurement apparatus 10 can be measured.

In the drawing apparatus 500 according to the embodiment, the measurement apparatus 10 measures the position (for example, Z direction) of a mark formed on a substrate at high accuracy, and the interferometer 70 measures the position of the substrate stage 502 at this time. Based on the measured positions of the mark and substrate stage 502, the drawing apparatus 500 moves the substrate stage 502 to the drawing position of the electron optical system 501. A desired pattern can therefore be drawn on a substrate at high accuracy. Note that a reference mark for measuring the position of an electron beam emitted by the electron optical system 501, or a reference mark for measuring the position of the measurement apparatus 10 may be arranged on the substrate stage 502. In this case, the drawing apparatus 500 measures not only the mark formed on the substrate but also the reference mark arranged on the substrate stage 502 by using the measurement apparatus 10. While controlling the position of the substrate stage 502 based on these measurement results, the drawing apparatus 500 performs drawing on the substrate 506. Hence, a desired pattern can be drawn on the substrate at high accuracy.

The drawing apparatus 500 including a plurality of measurement apparatuses 10 such as a measurement apparatus 10X for measuring an X measurement mark and a measurement apparatus 10Y for measuring a Y measurement mark will be described. FIG. 14 is a view showing the drawing apparatus 500 including the measurement apparatus 10X for measuring an X measurement mark and the measurement apparatus 10Y for measuring a Y measurement mark, when viewed from the Z direction. The drawing apparatus 500 of this type includes a plurality of (two) interferometers 70. An interferometer 70X measures the X position of the substrate stage 502 (not shown in FIG. 14) with respect to the position of the measurement apparatus 10X. Similarly, an interferometer 70Y measures the Y position of the substrate stage 502 with respect to the position of the measurement apparatus 10Y. The drawing apparatus 500 shown in FIG. 14 measures an X measurement mark formed on the substrate by moving the X measurement mark to below the measurement apparatus 10X by the substrate stage 502. Similarly, the drawing apparatus 500 measures a Y measurement mark formed on the substrate by moving the Y measurement mark to below the measurement apparatus 10Y by the substrate stage 502. The drawing apparatus 500 measures the X and Y measurement marks by using the measurement apparatuses 10X and 10Y, respectively, and performs drawing on the substrate 506 while controlling the position of the substrate stage 502 based on these measurement results. Therefore, a desired pattern can be drawn on the substrate at high accuracy.

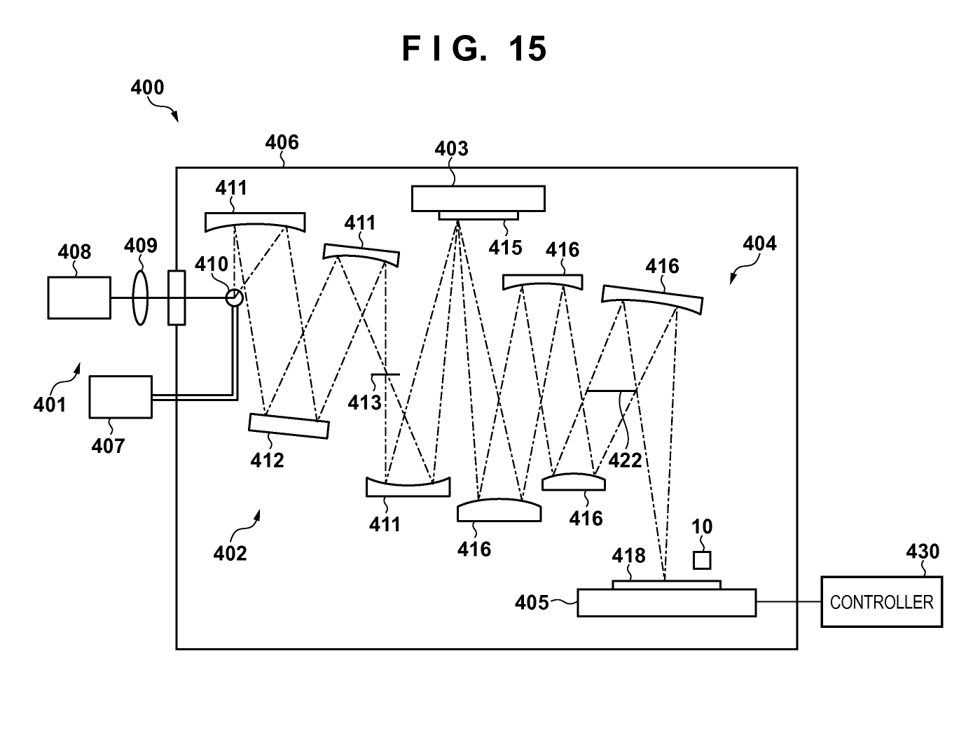

Next, the exposure apparatus 400 will be described with reference to FIG. 15. The exposure apparatus 400 includes a light source 401, an illumination optical system 402, a reticle stage 403 which holds a reticle 415, a projection optical system 404, a substrate stage 405 which is movable while holding a substrate 418, and a controller 430 which controls the movement of the substrate stage 405. In the exposure apparatus 400, a vacuum chamber 406 covers the illumination optical system 402, reticle stage 403, projection optical system 404, and substrate stage 405. The light source 401 is an EUV light source in the embodiment, and includes a target supply unit 407, pulse laser irradiation unit 408, and condenser lens 409. The light source 401 irradiates, with a pulse laser from the pulse laser irradiation unit 408 via the condenser lens 409, for example, a target material supplied from the target supply unit 407 into the vacuum chamber 406. This can generate a high-temperature plasma 410 to radiate EUV light (for example, a wavelength of 13.5 nm). As the target material, a metal thin film, inert gas, droplet, or the like is usable. The target material can be supplied into the vacuum chamber 406 by a method such as a gas jet. Note that the pressure in the vacuum chamber 406 is maintained at 10⁻⁴ to 10⁻⁵ Pa. The illumination optical system 402 can include a plurality of mirrors 411 (multi-layer mirrors or oblique incidence mirrors), an optical integrator 412, and an aperture 413. EUV light isotropically radiated from the plasma 410 is condensed by the plurality of mirrors 411 and optical integrator 412, and uniformly irradiates the reticle 415. The aperture 413 defines the irradiation region of the reticle 415 into a predetermined shape (for example, arc). The projection optical system 404 includes a plurality of mirrors 416 and an aperture 422. The projection optical system 404 guides the EUV light reflected by the reticle 415 to the substrate 418 held by the substrate stage 405.

The exposure apparatus 400 includes the measurement apparatus 10 which measures the position of a mark formed on a substrate to align the substrate 418 and the reticle 415 or align a plurality of shot regions formed on the substrate. As the measurement apparatus 10, for example, the measurement apparatus 10 described in the first embodiment is applicable. In the exposure apparatus 400, the controller 430 controls the position of the substrate stage 405 based on the mark position measured by the measurement apparatus 10. Consequently, the position of the mark formed on the substrate, that is, the position of the substrate can be measured at high accuracy.

### Embodiment of Method of Manufacturing Article

A method of manufacturing an article according to an embodiment of the present invention is suitable for manufacturing a microdevice such as a semiconductor device, and an article such as an element having a microstructure. The method of manufacturing an article according to the embodiment includes a step of forming a latent image pattern on a photosensitive agent applied to a substrate (object) by using the aforementioned lithography apparatus (drawing apparatus or exposure apparatus) (step of exposing a substrate), and a step of processing the substrate (object) on which the latent image pattern is formed in the preceding step. Further, the manufacturing method can include other well-known steps (for example, oxidization, deposition, vapor deposition, doping, planarization, etching, resist removal, dicing, bonding, and packaging). The method of manufacturing an article according to the embodiment is superior to a conventional method in at least one of the performance, quality, productivity, and production cost of an article.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-009615 filed on Jan. 22, 2013, which is hereby incorporated by reference herein in its entirety.

1. A detection apparatus including a detector configured to detect a mark including a plurality of patterns arrayed on an object in a first direction, the apparatus comprising:
a support configured to support at least a part of the detector,
wherein the support is configured to support the at least the part such that a displacement of the at least the part in a second direction corresponding to the first direction is smaller than a displacement of the at least the part in a third direction perpendicular to the second direction.

2. The apparatus according to claim 1, wherein
the detector includes an optical system, and
the support includes a supporting surface parallel to an optical axis of the optical system and the second direction, and is configured to support the at least the part with the supporting surface.

3. The apparatus according to claim 2, wherein the support includes at least one supporting member, and is configured to support the at least the part with the supporting surface via the supporting member.

4. The apparatus according to claim 3, wherein a plurality of the supporting member is respectively arranged at a plurality of positions symmetrical with respect to a plane including the optical axis and being perpendicular to the supporting surface.

5. The apparatus according to claim 1, further comprising a container airtightly containing the at least the part.

6. The apparatus according to claim 1, wherein the second direction is a direction parallel to the first direction.

7. The apparatus according to claim 1, wherein the detector is configured to detect, as the plurality of patterns, a plurality of line patterns.

8. A measurement apparatus which measures a position of a mark including a plurality of patterns arrayed on an object in a first direction, the measurement apparatus comprising:
a detection apparatus including a detector configured to detect a mark including a plurality of patterns arrayed on an object in a first direction, the apparatus comprising a support configured to support at least a part of the detector,
wherein the support is configured to support the at least the part such that a displacement of the at least the part in a second direction corresponding to the first direction is smaller than a displacement of the at least the part in a third direction perpendicular to the second direction; and
a processor configured to obtain the position of the mark based on an output from the detection apparatus.

9. A lithography apparatus which forms a pattern on an object, the lithography apparatus comprising:
a measurement apparatus which measures a position of a mark including a plurality of patterns arrayed on an object in a first direction, the measurement apparatus comprising:
a detection apparatus including a detector configured to detect a mark including a plurality of patterns arrayed on an object in a first direction, the apparatus comprising:
a support configured to support at least a part of the detector,
wherein the support is configured to support the at least the part such that a displacement of the at least the part in a second direction corresponding to the first direction is smaller than a displacement of the at least the part in a third direction perpendicular to the second direction; and
a processor configured to obtain the position of the mark based on an output from the detection apparatus;
a stage configured to hold the object and be movable; and
a controller configured to control a position of the stage based on an output from the measurement apparatus.

10. A method of manufacturing an article, the method comprising steps of:
forming a pattern on an object using a lithography apparatus; and
processing the object, on which the pattern has been formed, to manufacture the article,
wherein the lithography apparatus comprises:
a measurement apparatus configured to measure a position of a mark including a plurality of patterns arrayed on the object in a first direction;
a stage configured to hold the object and be movable; and
a controller configured to control a position of the stage based on an output from the measurement apparatus,
wherein the measurement apparatus includes
a detection apparatus including a detector configured to detect the mark and a support configured to support at least a part of the detector; and
a processor configured to obtain the position of the mark based on an output from the detection apparatus,
wherein the support is configured to support the at least the part such that a displacement of the at least the part in a second direction corresponding to the first direction is smaller than a displacement of the at least the part in a third direction perpendicular to the second direction.
